(19) United States
(12) Patent Application Publication
(10) Pub. No.: US 2025/0040067 A1
(43) Pub. Date: Jan. 30, 2025

(54) DISPLAY DEVICE AND MANUFACTURING METHOD FOR THE SAME

(71) Applicant: SAMSUNG DISPLAY CO., LTD., YONGIN-SI (KR)

(72) Inventors: MIN-HOON CHOI, Yongin-si (KR); SUNGHYUN KIM, Yongin-si (KR); SEUNGHO KIM, Yongin-si (KR); CHEOLMIN PARK, Yongin-si (KR); EUNWON SEO, Yongin-si (KR); JIN-WON JANG, Yongin-si (KR); SEONGJIN HWANG, Yongin-si (KR)

(21) Appl. No.: 18/735,840

(22) Filed: Jun. 6, 2024

(30) Foreign Application Priority Data
Jul. 28, 2023 (KR) 10-2023-0099216

(51) Int. Cl. H05K 5/02

(52) U.S. Cl. CPC H05K 5/0217

(57) ABSTRACT

A display device includes a display panel having a first non-folding region, a folding region, and a second non-folding region consecutively arranged in a first direction. The folding region is adjacent to the first and second non-folding regions and is foldable about a folding axis. A lower substrate is disposed under the display panel. The lower substrate includes a spacing portion and a pattern portion. The spacing portion overlaps the folding region on a plane. The pattern portion is spaced apart from the display panel by the spacing portion in a thickness direction of the display device. The pattern portion includes a plurality of holes.

### CROSS-REFERENCE TO RELATED APPLICATIONS

This application claims priority under 35 U.S.C. § 119 to Korean Patent Application No. 10-2023-0099216, filed on Jul. 28, 2023, in the Korean Intellectual Property Office, the disclosure of which is incorporated by reference in its entirety herein.

### 1. TECHNICAL FIELD

Embodiments of the present disclosure described herein relate to a display device including a lower substrate and a method for manufacturing the display device.

### 2. DISCUSSION OF RELATED ART

Display devices display various images on display screens and provide information to users. In general, display devices display information on allocated screens. Flexible display devices are being developed which include a flexible display panel that can be foldable, rollable or bendable, unlike rigid display devices. Since flexible display devices have shapes which can be changed in various ways, the flexible display devices may be carried regardless of the sizes of existing screens. Therefore, user convenience and portability of the display device may be increased.

In the development of the flexible display devices, a lower substrate disposed under the flexible display panel is also being developed. For example, the lower substrate may reduce stress applied to the display panel when the display panel is folded, rolled or bent and may absorb an external impact.

### SUMMARY

Embodiments of the present disclosure provide a display device including a lower substrate.

Embodiments of the present disclosure provide a method for manufacturing a display device including a lower substrate.

According to an embodiment of the present disclosure, a display device includes a display panel having a first non-folding region, a folding region, and a second non-folding region consecutively arranged in a first direction. The folding region is adjacent to the first and second non-folding regions and is foldable about a folding axis. A lower substrate is disposed under the display panel. The lower substrate includes a spacing portion and a pattern portion. The spacing portion overlaps the folding region on a plane. The pattern portion is spaced apart from the display panel by the spacing portion in a thickness direction of the display device. The pattern portion includes a plurality of holes.

In an embodiment, a width of the pattern portion in the first direction may increase as a distance from the display panel increases in the thickness direction of the display device.

In an embodiment, the lower substrate may include a first region overlapping the first non-folding region, a second region overlapping the second non-folding region, and a third region overlapping the folding region. The third region includes the spacing portion and the pattern portion. The first region, the second region, and the third region may include a same material as each other.

In an embodiment, the lower substrate may be a glass substrate.

In an embodiment, the spacing portion may have a height that is less than or equal to one-third of a thickness of the lower substrate.

In an embodiment, the spacing portion may have a height in a range of about 10 micrometers to about 100 micrometers.

In an embodiment, the spacing portion may have a greater width in the first direction than a width of the folding region in the first direction.

In an embodiment, the spacing portion may have a greater width in the first direction than a width of the pattern portion in the first direction.

In an embodiment, the display device may further include a resin material filling the spacing portion.

In an embodiment, the plurality of holes may extend in a second direction crossing the first direction. The plurality of holes may include a first hole group and a second hole group spaced apart from each other in the first direction. The first hole group and the second hole group may be staggered with respect to each other.

According to an embodiment of the present disclosure, a method for manufacturing a display device includes preparing a preliminary lower substrate including a first region, a second region spaced apart from the first region in a first direction, and a third region defined between the first region and the second region. A first laser is applied along a boundary of the third region. A second laser is applied between portions that the first laser is applied. A display panel is formed on the preliminary lower substrate. A spacing portion and a pattern portion is formed by etching the preliminary lower substrate. The pattern portion is spaced apart from the display panel by the spacing portion in a thickness direction of the display device. The pattern portion includes a plurality of holes.

In an embodiment, the method may further include placing an etching protection film on the display panel.

In an embodiment, the method may further include filling the spacing portion with a resin material.

In an embodiment, the second laser may have a higher intensity than an intensity of the first laser.

In an embodiment, the applying of the first laser may include focusing the first laser on an upper portion of the preliminary lower substrate and etching a portion of the preliminary lower substrate.

In an embodiment, the applying of the first laser may include focusing the first laser on a middle portion of the preliminary lower substrate and etching a portion of the preliminary lower substrate.

In an embodiment, the applying of the second laser may include focusing the second laser on an upper portion of the preliminary lower substrate and etching a portion of the preliminary lower substrate.

In an embodiment, the applying of the second laser may include focusing the second laser on a middle portion of the preliminary lower substrate and etching a portion of the preliminary lower substrate.

In an embodiment, the applying of the second laser may include focusing the second laser on a lower portion of the preliminary lower substrate and etching a portion of the preliminary lower substrate.

In an embodiment, the applying of the second laser may include focusing the second laser on an upper portion, a middle portion, and a lower portion of the preliminary lower substrate and etching a portion of the preliminary lower substrate.

### BRIEF DESCRIPTION OF THE DRAWINGS

The above and other objects and features of the present disclosure will become apparent by describing in detail non-limiting embodiments thereof with reference to the accompanying drawings.

FIG. 1A is a perspective view illustrating a display device in an unfolded state according to an embodiment of the present disclosure.

FIG. 1B is a perspective view illustrating a folding operation of the display device according to an embodiment of the present disclosure.

FIG. 1C is a plan view illustrating the display device in a folded state according to an embodiment of the present disclosure.

FIG. 1D is a perspective view illustrating a folding operation of the display device according to an embodiment of the present disclosure.

FIG. 2 is a cross-sectional view of the display device according to an embodiment of the present disclosure.

FIG. 3 is a cross-sectional view of a display panel according to an embodiment of the present disclosure.

FIG. 4 is a perspective view of a portion of the display device according to an embodiment of the present disclosure.

FIG. 5 is a perspective view of a lower substrate according to an embodiment of the present disclosure.

FIG. 6 is a cross-sectional view of a portion of the folded display device according to an embodiment of the present disclosure.

FIG. 7 is a perspective view of a portion of the display device according to an embodiment of the present disclosure.

FIGS. 8A to 8D are cross-sectional views illustrating some steps of a display device manufacturing method according to embodiments of the present disclosure.

FIGS. 9A and 9B are cross-sectional views illustrating some steps of a display device manufacturing method according to embodiments of the present disclosure.

FIGS. 10A and 10B are cross-sectional views illustrating some steps of a display device manufacturing method according to embodiments of the present disclosure.

FIGS. 11A and 11B are cross-sectional views illustrating some steps of a display device manufacturing method according to embodiments of the present disclosure.

FIGS. 12A and 12B are cross-sectional views illustrating some steps of a display device manufacturing method according to embodiments of the present disclosure.

### DETAILED DESCRIPTION OF EMBODIMENTS

In this specification, when it is mentioned that a component (or, an area, a layer, a part, etc.) is referred to as being “on”, “connected to” or “coupled to” another component, this means that the component may be directly on, connected to, or coupled to the other component or a third component may be present therebetween. When it is mentioned that a component is “directly on”, “directly connected to” or “directly coupled to” another component, no intervening component is present.

Identical reference numerals refer to identical components. Additionally, in the drawings, the thicknesses, proportions, and dimensions of components may be exaggerated for effective description. As used herein, the term “and/or” includes all of one or more combinations defined by related components.

Terms such as first, second, and the like may be used to describe various components, but the components should not be limited by the terms. The terms may be used only for distinguishing one component from other components. For example, without departing the scope of embodiments of the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship of components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

Hereinafter, embodiments of the present disclosure will be described with reference to the accompanying drawings.

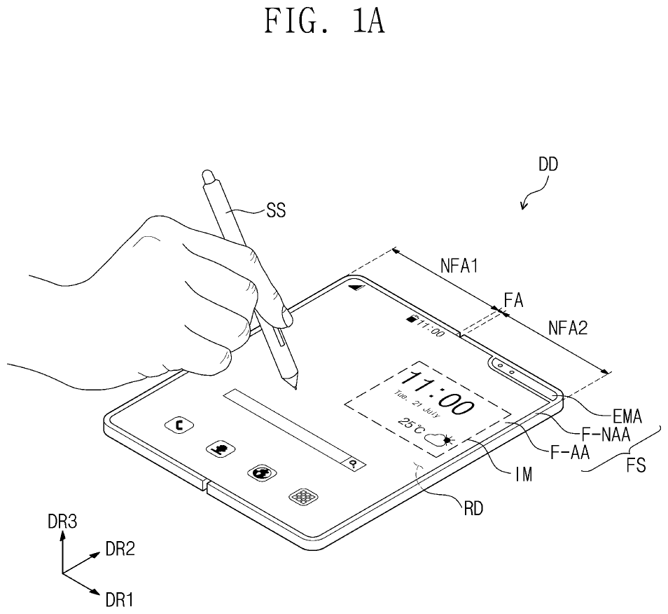

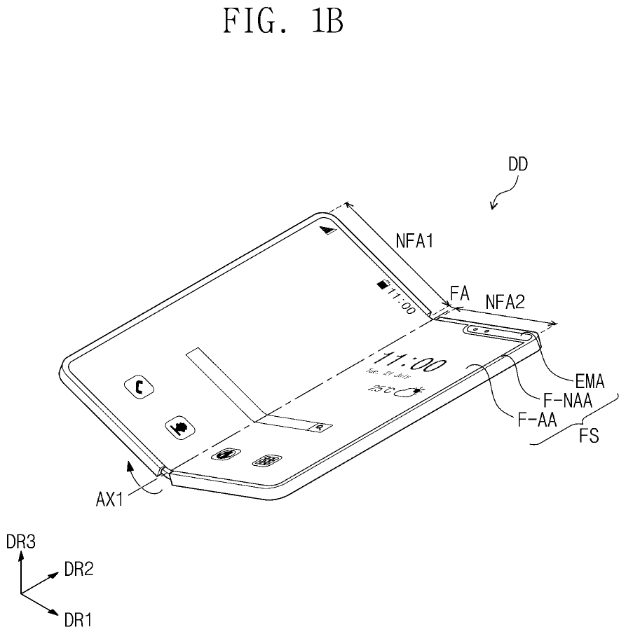

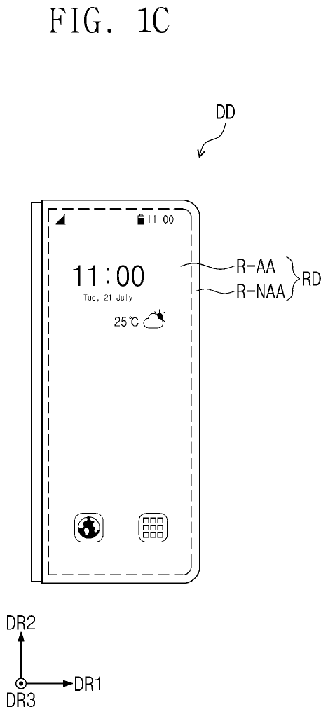

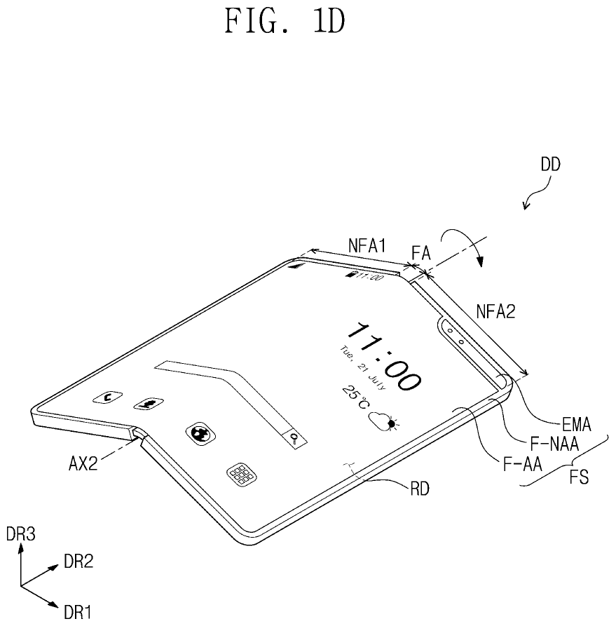

FIG. 1A is a perspective view illustrating a display device DD in an unfolded state according to an embodiment of the present disclosure.

Referring to FIG. 1A, the display device DD may be a device activated depending on an electrical signal. The display device DD may include various embodiments. For example, in an embodiment the display device DD may include a tablet computer, a notebook computer, a computer, a smart television, or the like. However, embodiments of the present disclosure are not necessarily limited thereto. In FIG. 1A, the display device DD is illustrated as a smart phone for convenience of explanation.

In an embodiment, the display device DD may display an image IM in a third direction DR3 on a first display surface FS that is defined in a plane parallel to a first direction DR1 and a second direction DR2. The first display surface FS on which the image IM is displayed may correspond to the front surface of the display device DD. In an embodiment, the image IM may include at least one still image and/or at least one dynamic image. In FIG. 1A, an Internet search window, a clock, calendar and weather window, and a plurality of applications are illustrated as examples of the image IM. However, embodiments of the present disclosure are not necessarily limited thereto.

In an embodiment, upper surfaces (e.g., front surfaces) and lower surfaces (e.g., rear surfaces) of components are defined based on the direction in which the image IM is displayed. The front surfaces and the rear surfaces may be opposite each other in the third direction DR3, and the normal directions of the front surfaces and the rear surfaces may be parallel to the third direction DR3.

The separation distance between the front surface and the rear surface of the display device DD in the third direction DR3 may correspond to the thickness/height of the display device DD in the third direction DR3. The directions indicated by the first to third directions DR1, DR2, and DR3 may be relative concepts and may be changed to different directions.

The display device DD may sense an external input applied to the display device DD. In an embodiment, the external input may include various forms of inputs provided from outside the display device DD. For example, the external input may include not only direct contact by a part of a user's body, such as the user's hand, or an input device, such as a pen, but also an external input (e.g., hovering) that is applied in proximity to the display device DD or applied adjacent to the display device DD at a predetermined distance. The external input may have various forms such as force, pressure, temperature, light, and the like.

FIG. 1A illustrates an external input through a pen SS of the user. In some embodiments, the pen SS may be attached to the inside or outside of the display device DD and may be detached from the display device DD. The display device DD may provide and receive signals corresponding to the attachment and detachment of the pen SS.

In an embodiment, the display device DD may include the first display surface FS and a second display surface RD. The first display surface FS may include a first active region F-AA, a first peripheral region F-NAA, and an electronic module region EMA. The second display surface RD may be defined as a surface facing away from at least a portion of the first display surface FS (e.g., in the third direction DR3).

The first active region F-AA may be a region that is activated depending on an electrical signal. The first active region F-AA may be a region on which the image IM is displayed and that senses an input of the pen SS.

The first peripheral region F-NAA may be adjacent to the first active region F-AA (e.g., in the first and/or second directions DR1, DR2). In an embodiment, the first peripheral region F-NAA may have a predetermined color. The first peripheral region F-NAA may surround the first active region F-AA (e.g., in the first and/or second directions DR1, DR2). Accordingly, the shape of the first active region F-AA may be substantially defined by the first peripheral region F-NAA. However, embodiments of the present disclosure are not necessarily limited thereto. For example, in some embodiments the first peripheral region F-NAA may be disposed adjacent to only one side of the first active region F-AA, or may be omitted.

The electronic module region EMA may have various electronic modules disposed therein. For example, in an embodiment the electronic modules may include at least one of a camera, a speaker, a light detection sensor, and a heat detection sensor. In some embodiments, the electronic module region EMA may sense an external object received through the display surfaces FS and RD, or may provide a sound signal, such as a voice, to the outside through the display surfaces FS and RD. The electronic modules may include a plurality of components and are not necessarily limited to any one embodiment.

The electronic module region EMA may be surrounded by the first peripheral region F-NAA. However, embodiments of the present disclosure are not necessarily limited thereto. For example, in an embodiment the electronic module region EMA may be surrounded by the first active region F-AA and the first peripheral region F-NAA, and the electronic module region EMA may be disposed in the first active region F-AA.

The display device DD according to an embodiment may include at least one folding region FA and a plurality of non-folding regions, such as first and second non-folding regions NFA1 and NFA2, extending from the folding region FA. For example, the first non-folding region NFA1, the folding region FA, and the second non-folding region NFA2 may be arranged in the first direction DR1. For example, the first non-folding region NFA1 may extend from the folding region FA in the direction opposite to the first direction DR1, and the second non-folding region NFA2 may extend from the folding region FA in the first direction DR1.

The folding region FA may be referred to as the foldable region, and the first and second non-folding regions NFA1 and NFA2 may be referred to as the non-foldable regions. The folding region FA may be adjacent to the first non-folding region NFA1 and the second non-folding region NFA2 and may be folded about a folding axis AX1 or AX2 (refer to FIG. 1B or 1D).

FIG. 1B is a perspective view illustrating a folding operation of the display device DD according to an embodiment of the present disclosure.

Referring to FIG. 1B, the display device DD according to an embodiment may be folded about the first folding axis AX1 that extends in the second direction DR2. In an embodiment, the folding region FA may have a predetermined curvature and a predetermined radius of curvature in the folded state of the display device DD. The display device DD may be folded about the first folding axis AX1 and may be changed to an in-folded state in which the first non-folding region NFA1 and the second non-folding region NFA2 face each other and the first display surface FS is not exposed to the outside.

FIG. 1C is a plan view illustrating the display device DD in a folded state according to an embodiment of the present disclosure.

Referring to FIG. 1C, when the display device DD according to an embodiment is in an in-folded state, the second display surface RD may be visible to the user. In this case, the second display surface RD may include a second active region R-AA that displays an image. The second active region R-AA may be a region activated depending on an electrical signal. In an embodiment, the second active region R-AA may be a region on which an image is displayed and that senses various forms of external inputs.

A second peripheral region R-NAA may be adjacent to the second active region R-AA (e.g., in the first and/or second directions DR1, DR2). In an embodiment, the second peripheral region R-NAA may have a predetermined color. The second peripheral region R-NAA may surround the second active region R-AA (e.g., in the first and/or second directions DR1, DR2). Furthermore, in an embodiment the second display surface RD may further include an electronic module region in which electronic modules including various components are disposed. However, embodiments of the present disclosure are not necessarily limited thereto.

FIG. 1D is a perspective view illustrating a folding operation of the display device DD according to an embodiment of the present disclosure.

Referring to FIG. 1D, the display device DD according to an embodiment may be folded about the second folding axis AX2 that extends in the second direction DR2. The display device DD may be folded about the second folding axis AX2 and may be changed to an out-folded state in which the first display surface FS is exposed to the outside and the second display surface RD is not exposed to the outside. In an embodiment of the present disclosure, the display device DD may be configured such that an in-folding operation and an out-folding operation may be repeatedly performed from an unfolded state of the display device DD. However, embodiments of the present disclosure are not necessarily limited thereto.

In FIGS. 1A to 1D, the display device DD is illustrated as being folded about one folding axis AX1 or AX2. However, the number of folding axes and the number of non-folding regions depending on the number of folding axes are not necessarily limited thereto. For example, in an embodiment the display device DD may be folded about a plurality of folding axes such that a portion of the first display surface FS and a portion of the second display surface RD face each other.

FIG. 2 is a cross-sectional view of the display device DD according to an embodiment of the present disclosure.

Referring to FIG. 2, the display device DD may include a window module 300, an optical film 200, a display panel 100, and a lower substrate CS. In addition, the display device DD may further include adhesive layers 1031, 1032, 1020, and 1010 that bond the components.

In an embodiment, the adhesive layers 1031, 1032, 1020, and 1010, which will be described below, may be transparent adhesive layers including one of a pressure sensitive adhesive (PSA) film, an optically clear adhesive (OCA) film, and an optically clear resin (OCR). However, embodiments of the present disclosure are not necessarily limited thereto. Furthermore, at least one adhesive layer among the adhesive layers 1031, 1032, 1020, and 1010 may be omitted.

The window module 300 may be disposed on the display panel 100. In an embodiment, the window module 300 may be coupled with a housing to define the exterior of the display device DD and may protect the display panel 100. In an embodiment, the window module 300 may include a glass substrate 330, a window protection layer 320, and a light blocking pattern 340.

The glass substrate 330 may include a material having high light transmittance. In an embodiment, the glass substrate 330 may be a chemically strengthened glass substrate. The glass substrate 330 may minimize a crease even though folding and unfolding operations are repeated.

The window protection layer 320 may be disposed on the glass substrate 330 (e.g., in the third direction DR3). The window protection layer 320 and the glass substrate 330 may be coupled to each other by the adhesive layer 1031 disposed therebetween (e.g., in the third direction DR3). In an embodiment, the window protection layer 320 may include a plastic film. For example, the window protection layer 320 may include at least one of polyimide, polycarbonate, polyamide, triacetylcellulose, polymethylmethacrylate, and polyethylene terephthalate. However, embodiments of the present disclosure are not necessarily limited thereto.

The light blocking pattern 340 may be disposed on (e.g., disposed directly thereon) the lower surface of the window protection layer 320. The light blocking pattern 340 may be disposed on one surface of the window protection layer 320 that faces the glass substrate 330. In an embodiment, the adhesive layer 1031 may cover the light blocking pattern 340. However, embodiments of the present disclosure are not necessarily limited thereto.

In an embodiment, the light blocking pattern 340 may be a colored light blocking film and may be formed by, for example, a coating method. In an embodiment, the light blocking pattern 340 may include a base material and a dye or pigment mixed in the base material. Accordingly, the user may recognize the first peripheral region F-NAA (refer to FIG. 1A) of the display device DD by the color of the light blocking pattern 340. For example, the light blocking pattern 340 may overlap the first peripheral region F-NAA.

Although the light blocking pattern 340 of FIG. 2 is illustrated as being spaced apart inwardly from the end of the window protection layer 320 by a predetermined distance (e.g., in the first direction DR1), embodiments of the present disclosure are not necessarily limited thereto. For example, in an embodiment the light blocking pattern 340 may be disposed on the bottom of the window protection layer 320 so as to be aligned with the end of the window protection layer 320. Furthermore, the light blocking pattern 340 disposed on the lower surface of the window protection layer 320 is illustrated in FIG. 2 as an example. However, embodiments of the present disclosure are not necessarily limited thereto. For example, in some embodiments the light blocking pattern 340 may be disposed on the upper surface of the window protection layer 320, or may be disposed on one of the upper surfaces and the lower surface of the glass substrate 330.

The window module 300 may further include a hard coating layer 310. The hard coating layer 310 may be disposed on the window protection layer 320 (e.g., disposed directly thereon in the third direction DR3) and may be disposed in the outermost layer of the window module 300 accordingly. In an embodiment, the hard coating layer 310 may be a functional layer for increasing usage characteristics of the display device DD and may be provided on the window protection layer 320 by coating. For example, in an embodiment anti-fingerprint properties, anti-contamination properties, anti-reflection properties, or anti-scratch properties may be increased by the hard coating layer 310.

The optical film 200 may be disposed under the window module 300. The optical film 200 and the window module 300 may be coupled to each other by the adhesive layer 1032. The optical film 200 may reduce the external light reflectance of the display panel 100 with respect to light incident to the display panel 100. In an embodiment, the optical film 200 may further include at least one of an anti-reflection film, a polarizer film, a color filter, and a gray filter.

The display panel 100 may be disposed under the optical film 200. In an embodiment, the display panel 100 and the optical film 200 may be coupled to each other by the adhesive layer 1020. In an embodiment, the display panel 200 may function as an output device that displays an image and may function as an input device that senses an input applied from the outside. For example, the display panel 100 may include a display layer and a sensor layer. The display layer may be a component that substantially generates an image. In an embodiment, the display layer may be one of an organic light emitting display panel, a quantum-dot display panel, and an inorganic light emitting display panel. However, embodiments of the present disclosure are not necessarily limited thereto.

A first non-folding region NFA1, a folding region FA, and a second non-folding region NFA2 may be arranged in the first direction DR1 in the display panel 100. The first non-folding region NFA1, the folding region FA, and the second non-folding region NFA2 defined in the display panel 100 may be substantially the same as the first non-folding region NFA1, the folding region FA, and the second non-folding region NFA2 of the display device DD described above with reference to FIG. 1A.

The lower substrate CS may be disposed under the display panel 100. In an embodiment, the lower substrate CS and the display panel 100 may be coupled to each other by the adhesive layer 1010. The lower substrate CS may protect the display panel 100. For example, in an embodiment the lower substrate CS may reduce stress applied to the display panel 100 when the display device DD is folded. In addition, the lower substrate CS may prevent infiltration of external moisture into the display panel 100 and may absorb an external impact.

The lower substrate CS may include a first region AR1, a second region AR2, and a third region AR3. The first region ARI may overlap the first non-folding region NFA1 of the display panel 100, the second region AR2 may overlap the second non-folding region NFA2 of the display panel 100, and the third region AR3 may overlap the folding region FA. For example, the first region AR1, the third region AR3, and the second region AR2 of the lower substrate CS may be arranged in the first direction DR1. In an embodiment, the first region AR1, the second region AR2, and the third region AR3 may include the same material as each other. For example, in an embodiment the lower substrate CS may include a glass substrate. However, embodiments of the present disclosure are not necessarily limited thereto.

A spacing portion SP and a pattern portion PP may be defined in the third region AR3 of the lower substrate CS. The spacing portion SP of the lower substrate CS may overlap the folding region FA of the display panel 100 on the plane (e.g., in the third direction DR3). The pattern portion PP of the lower substrate CS may be spaced apart from the display panel 100 by the spacing portion SP in a cross-sectional view and may include a plurality of holes HO. Detailed description about the lower substrate CS will be given below.

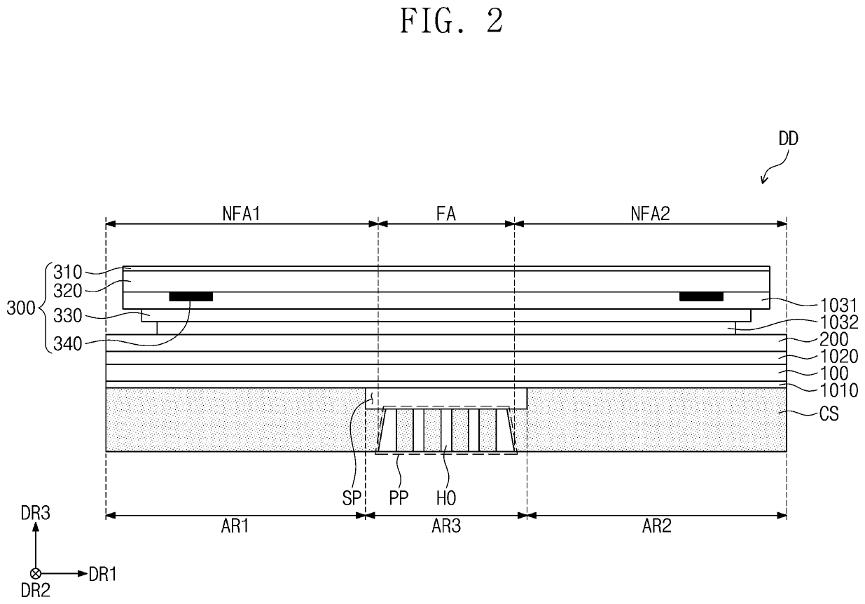

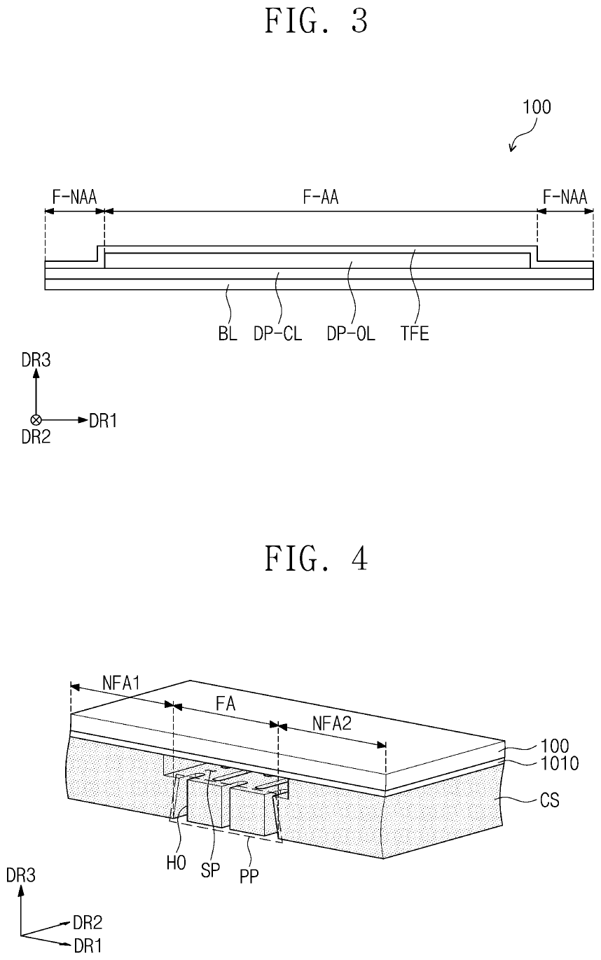

FIG. 3 is a cross-sectional view of the display panel 100 according to an embodiment of the present disclosure.

Referring to FIG. 3, in an embodiment the display panel 100 may include a base layer BL, a circuit layer DP-CL, a display element layer DP-OL, and an encapsulation layer TFE.

The base layer BL may provide a base surface on which the circuit layer DP-CL is disposed. In an embodiment, the base layer BL may be a rigid substrate. However, embodiments of the present disclosure are not necessarily limited thereto. For example, in some embodiments the base layer BL may be a flexible substrate.

The base layer BL may include the first active region F-AA and the first peripheral region F-NAA. Although the first active region F-AA and the first peripheral region F-NAA of FIG. 1A are illustrated in FIG. 3, embodiments of the present disclosure are not necessarily limited thereto. For example, the base layer BL may include the second active region R-AA and the second peripheral region R-NAA in some embodiments.

The first active region F-AA may be a region activated depending on an electrical signal. The first peripheral region F-NAA may be a region in which a drive circuit or drive wiring for driving elements disposed in the first active region F-AA, various types of signal lines for providing electrical signals, and pads are disposed.

The circuit layer DP-CL may be disposed on the base layer BL (e.g., disposed directly thereon in the third direction DR3). In an embodiment, the circuit layer DP-CL may include at least one insulating layer, drive elements, signal lines, and signal pads.

The display element layer DP-OL may be disposed on the circuit layer DP-CL (e.g., in the third direction DR3). The display element layer DP-OL may include light emitting elements disposed to overlap the first active region F-AA. The light emitting elements of the display element layer DP-OL may be electrically connected to the drive elements of the circuit layer CL and may provide source light through the first active region F-AA depending on signals of the drive elements to display an image, such as image IM (FIG. 1).

The encapsulation layer TFE may be disposed on the display element layer DP-OL and may seal the light emitting elements. The encapsulation layer TFE may include a plurality of insulating films. In an embodiment, the insulating films of the encapsulation layer TFE may be disposed to increase the optical efficiency of the light emitting elements or protect the light emitting elements.

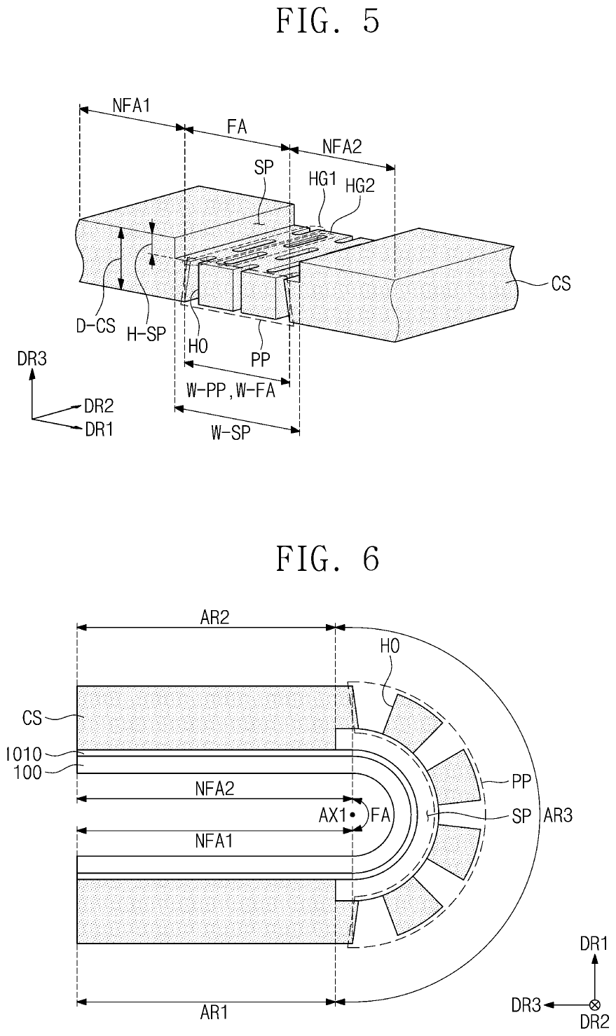

FIG. 4 is a perspective view of a portion of the display device DD according to an embodiment of the present disclosure. FIG. 5 is a perspective view of the lower substrate CS according to an embodiment of the present disclosure. FIG. 6 is a cross-sectional view of a portion of the folded display device DD according to an embodiment of the present disclosure. In FIGS. 4 and 6, the display panel 100, the lower substrate CS, and the adhesive layer 1010 are illustrated. In describing FIGS. 4 to 6, components identical or similar to the components described with reference to FIGS. 2 and 3 will be assigned with identical or similar reference numerals, and repetitive descriptions may be omitted for economy of description.

Referring to FIGS. 4 to 6, the spacing portion SP and the pattern portion PP may be defined in the lower substrate CS.

The spacing portion SP of the lower substrate CS may overlap the folding region FA of the display panel 100 on the plane (e.g., in the third direction DR3). In an embodiment, the spacing portion SP may be an empty space or region. In an embodiment, the height H_SP of the spacing portion SP may be less than or equal to one-third of the thickness D_CS of the lower substrate CS. For example, in an embodiment the height H_SP of the spacing portion SP may be in a range from about 10 micrometers to about 100 micrometers. For example, the thickness D_CS of the lower substrate CS may refer to the maximum thickness of the lower substrate CS.

The pattern portion PP of the lower substrate CS may be spaced apart from the display panel 100 (e.g., in the third direction DR3 which is a thickness direction of the display device DD) by the spacing portion SP in a cross-sectional view. In an embodiment, the width W-PP of the pattern portion PP in the first direction DR1 may gradually increase as the distance from the display panel 100 increases. For example, the width W-PP of the pattern portion PP in the first direction DR1 may gradually increase in the direction opposite to the third direction DR3.

The pattern portion PP may include the plurality of holes HO. The plurality of holes HO may extend in the second direction DR2 crossing the first direction DR1. In an embodiment, the plurality of holes HO may be spaced apart from each other in the first direction DR1 and the second direction DR2. In an embodiment, each of the plurality of holes HO may have a length in a range of about 200 micrometers or less in the first direction DR1.

The plurality of holes HO may include a first hole group HG1 and a second hole group HG2. Each of the holes HO included in the first hole group HG1 and the second hole group HG2 may extend longitudinally in the second direction DR2. The holes HO of the first hole group HG1 may be spaced apart from each other in the second direction DR2, and the holes HO of the second hole group HG2 may be spaced apart from each other in the second direction DR2. The first hole group HG1 and the second hole group HG2 may be spaced apart from each other in the first direction DR1. In an embodiment, the first hole group HG1 and the second hole group HG2 may be staggered with respect to each other.

In an embodiment, the width W-SP of the spacing portion SP of the lower substrate CS in the first direction DR1 may be greater than the width W-FA of the folding region FA in the first direction DR1. The width W-PP of the pattern portion PP of the lower substrate CS in the first direction DR1 may correspond to the width W-FA of the folding region FA of the display panel 100 in the first direction DR1. For example, the width W-SP of the spacing portion SP of the lower substrate CS in the first direction DR1 may be greater than the width W-PP of the pattern portion PP of the lower substrate CS in the first direction DR1.

According to an embodiment of the present disclosure, tensile stress generated in the pattern portion PP when the display device DD (refer to FIG. 1) is folded may not be transmitted to the display panel 100 because the lower substrate CS includes the spacing portion SP. Accordingly, a separation between the display panel 100 and the lower substrate CS may be reduced or eliminated.

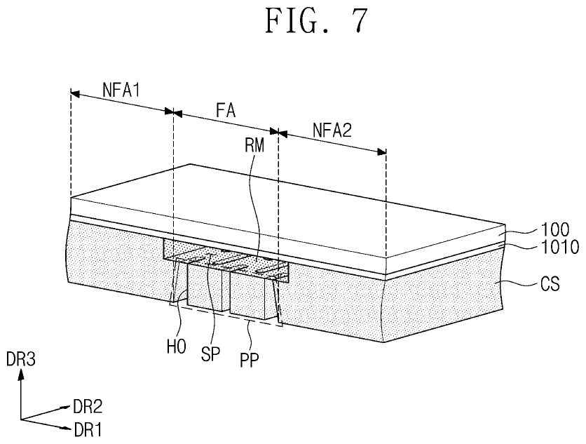

FIG. 7 is a perspective view of a portion of the display device according to an embodiment of the present disclosure. In FIG. 7, the display panel 100, the lower substrate CS, the adhesive layer 1010, and a resin material RM are illustrated. In describing FIG. 7, components identical or similar to the components described with reference to FIGS. 2 to 6 will be assigned with identical or similar reference numerals, and repetitive descriptions may be omitted for economy of description.

Referring to FIG. 7, the display device DD may further include the resin material RM. The spacing portion SP and the pattern portion PP may be defined in the lower substrate CS, and the resin material RM may fill the spacing portion SP of the lower substrate CS. In an embodiment, the resin material RM may include at least one of epoxy, urethane, and acrylate.

Since the resin material RM fills the spacing portion SP, a tensile force generated when the display device DD is folded may be decreased, and folding stability of the display device DD may be increased.

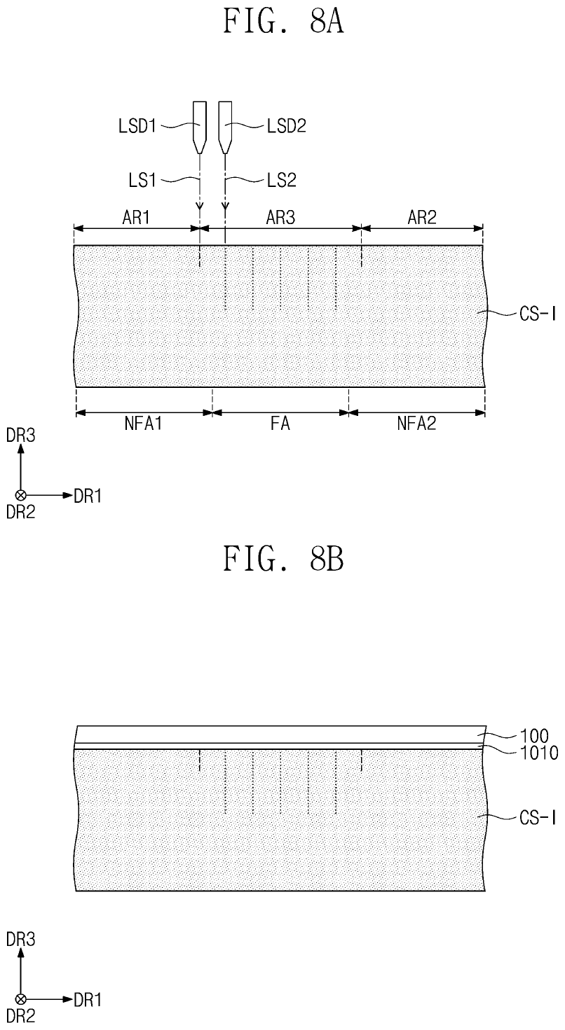

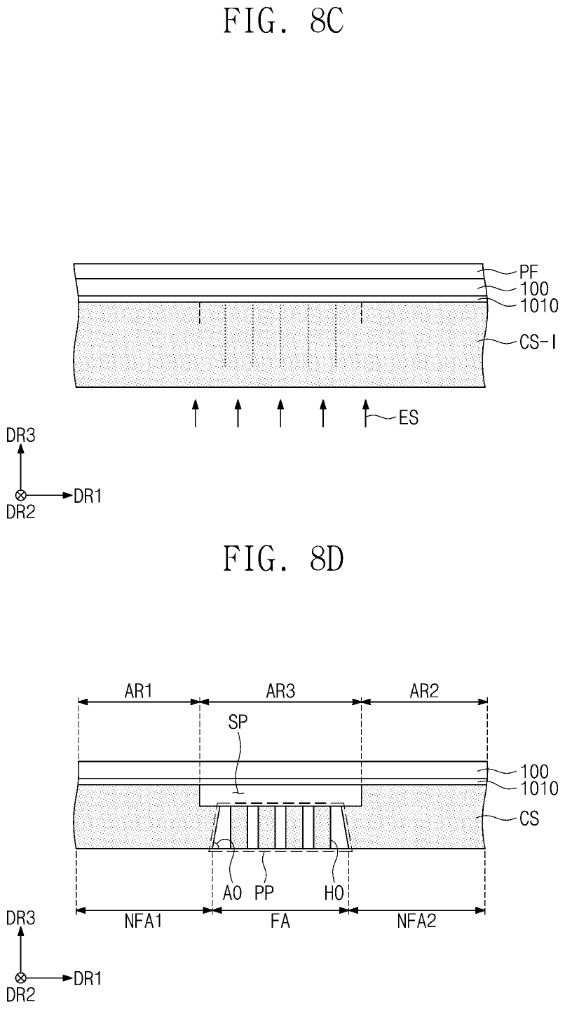

FIGS. 8A to 8D are cross-sectional views illustrating some steps of a display device manufacturing method according to embodiments of the present disclosure. In describing FIGS. 8A to 8D, components identical or similar to the components described with reference to FIGS. 2 to 7 will be assigned with identical or similar reference numerals, and repetitive descriptions may be omitted for economy of description.

The display device manufacturing method according to an embodiment of the present disclosure may include a step of preparing a preliminary lower substrate including a first region, a second region spaced apart from the first region in the first direction, and a third region defined between the first region and the second region (e.g., in the first direction), a step of applying a first laser along the boundary of the third region, a step of applying a second laser between portions to which the first laser is applied, a step of forming a display panel on the preliminary lower substrate, and a step of etching the preliminary lower substrate to form a spacing portion and a pattern portion that is spaced apart from the display panel by the spacing portion in a cross-sectional view and that includes a plurality of holes.

Referring to FIG. 8A, the display device manufacturing method of the present disclosure may include the step of preparing the preliminary lower substrate CS-I, the step of applying the first laser LS1, and the step of applying the second laser LS2.

The preliminary lower substrate CS-I may include the first region AR1, the second region AR2, and the third region AR3 (e.g., arranged in the first direction DR1). The second region AR2 may be spaced apart from the first region AR1 in the first direction DR1, and the third region AR3 may be defined between the first region AR1 and the second region AR2. For example, the first region AR1, the third region AR3, and the second region AR2 of the preliminary lower substrate CS-I may be arranged in the first direction DR1. In an embodiment, the preliminary lower substrate CS-I may have a thickness in a range of about 100 micrometers to about 500 micrometers.

A first laser device LSD1 may apply the first laser LS1 along the boundary of the third region AR3. For example, the first laser device LSD1 may apply the first laser LS1 along the boundary between the first region AR1 and the third region AR3 and the boundary between the second region AR2 and the third region AR3. In the cross-sectional view of FIG. 8A, it is illustrated that the first laser LS1 is applied twice. In an embodiment, the step of applying the first laser LS1 may include a step of focusing the first laser LSI on an upper portion of the preliminary lower substrate CS-I and etching a portion of the preliminary lower substrate CS-I. In an embodiment, the portion to which the first laser LS1 is applied may be the spacing portion SP (refer to FIG. 8D) of the lower substrate CS (refer to FIG. 8D) that will be described below.

Thereafter, a second laser device LSD2 may apply the second laser LS2 between the two portions to which the first laser LS1 is applied. In an embodiment, the intensity of the second laser LS2 may be higher than the intensity of the first laser LS1. The second laser LS2 may more deeply process the preliminary lower substrate CS-I than the first laser LS1. For example, the first laser LS1 may process the preliminary lower substrate CS-I to a depth in a range of about 100 micrometers or less, and the second laser LS2 may process the preliminary lower substrate CS-I to a depth in a range of about 100 micrometers or more. In the cross-sectional view of FIG. 8A, it is illustrated that a plurality of second lasers LS2 are applied between the portions to which the first laser LS1 is applied twice. However, embodiments of the present disclosure are not necessarily limited thereto.

In an embodiment, the step of applying the second laser LS2 may include a step of focusing the second laser LS2 on the upper portion of the preliminary lower substrate CS-I and etching a portion of the preliminary lower substrate CS-I. The portion to which the second laser LS2 is applied may be the pattern portion PP (refer to FIG. 8D) of the lower substrate CS (refer to FIG. 8D) that will be described below.

Although it has been described that the second laser LS2 is applied to the preliminary lower substrate CS-I after the first laser LS1 is applied first embodiments of the present disclosure are not necessarily limited thereto. For example, in some embodiments the first laser LS1 may be applied after the second laser LS2 is applied first, or the first laser LS1 and the second laser LS2 may be simultaneously applied.

Referring to FIG. 8B, the display device manufacturing method of the present disclosure may include the step of forming the display panel 100 on the preliminary lower substrate CS-I. The base layer BL (refer to FIG. 3) may be formed on the preliminary lower substrate CS-I on which the processes of applying the first and second lasers LS1 and LS2 (refer to FIG. 8A) are completely performed. The circuit layer DP-CL (refer to FIG. 3) may be formed on the base layer BL, and the display element layer DP-OL (refer to FIG. 3) may be formed on the circuit layer DP-CL. Thereafter, the display panel 100 may be formed by forming the encapsulation layer TFE on the display element layer DP-OL.

In a display device manufacturing method in the related art, a display device is manufactured by removing the preliminary lower substrate CS-I and coupling a panel protection film, a cover panel, and a lower metal plate to the bottom of the display panel 100. However, according to an embodiment of the present disclosure, a lower member protecting the display panel 100 may be formed using the preliminary lower substrate CS-I without removal of the preliminary lower substrate CS-I that carries or supports the base layer BL of the display panel 100. Accordingly, the panel protection film, the cover panel, and the lower metal plate in the related art may be replaced with the preliminary lower substrate. Thus, the display device manufacturing process may be simplified, and the weight of the display device may be reduced.

Referring to FIGS. 8C and 8D, the display device manufacturing method of the present disclosure may include a step of placing an etching protection film PF and the step of etching the preliminary lower substrate CS-I to form the spacing portion SP and the pattern portion PP. In an embodiment, the etching protection film PF may be disposed on the display panel 100 to protect the display panel 100 before the etching of the preliminary lower substrate CS-I.

Thereafter, the preliminary lower substrate CS-I may be etched from the bottom by an etchant ES. In an embodiment, the etchant ES may include at least one of HF, NaOH, and KOH. However, embodiments of the present disclosure are not necessarily limited thereto. For example, the preliminary lower substrate CS-I may be etched from the bottom, and the etchant ES may reach the lower surface of the display panel 100 (e.g., the lower surface of the adhesive layer 1010). In the process, the etchant ES may infiltrate into the bottom of the preliminary lower substrate CS-I and the portion to which the second laser LS2 is applied and may etch a portion of the preliminary lower substrate CS-I. The pattern portion PP of the lower substrate CS may be formed from the etched portion.

The spacing portion SP of the lower substrate CS may overlap the folding region FA of the display panel 100 on the plane (e.g., in the third direction DR3). In an embodiment, the spacing portion SP may be an empty space or region. In an embodiment, the height H_SP (refer to FIG. 6) of the spacing portion SP may be less than or equal to one-third of the thickness D_CS (refer to FIG. 6) of the lower substrate CS. For example, in an embodiment the height H_SP (refer to FIG. 6) of the spacing portion SP may be in a range from about 10 micrometers to about 100 micrometers.

Thereafter, an additional etching process having isotropic characteristics may be performed from the lower surface of the display panel 100 (or, the lower surface of the adhesive layer 1010). In the additional etching process, the etchant ES may infiltrate into the portion to which the first laser LS1 is applied and may etch a portion of the preliminary lower substrate CS-I. The spacing portion SP of the lower substrate CS may be formed from the etched portion.

The pattern portion PP of the lower substrate CS may be spaced apart from the display panel 100 by the spacing portion SP in a cross-sectional view. The width W-PP (refer to FIG. 6) of the pattern portion PP in the first direction DR1 may gradually increase as the distance from the display panel 100 increases. The pattern portion PP may include the plurality of holes HO. The plurality of holes HO may extend in the second direction DR2 crossing the first direction DR1. The plurality of holes HO may be spaced apart from each other in the first direction DR1 and the second direction DR2. In an embodiment, the pattern angle AO formed by the holes HO existing at the opposite ends of the pattern portion PP and the side surfaces of the pattern portion PP may be in a range of about 90 degrees or less. In an embodiment, the etched lower substrate CS may have a thickness in a range of about 30 micrometers to about 300 micrometers.

The display device manufacturing method of the present disclosure may further include a step of filling the spacing portion SP with the resin material RM (refer to FIG. 7). In an embodiment, the resin material RM may include at least one of epoxy, urethane, and acrylate. Since the resin material RM fills the spacing portion SP, a tensile force generated when the display device DD is folded may be decreased, and folding stability of the display device DD may be increased.

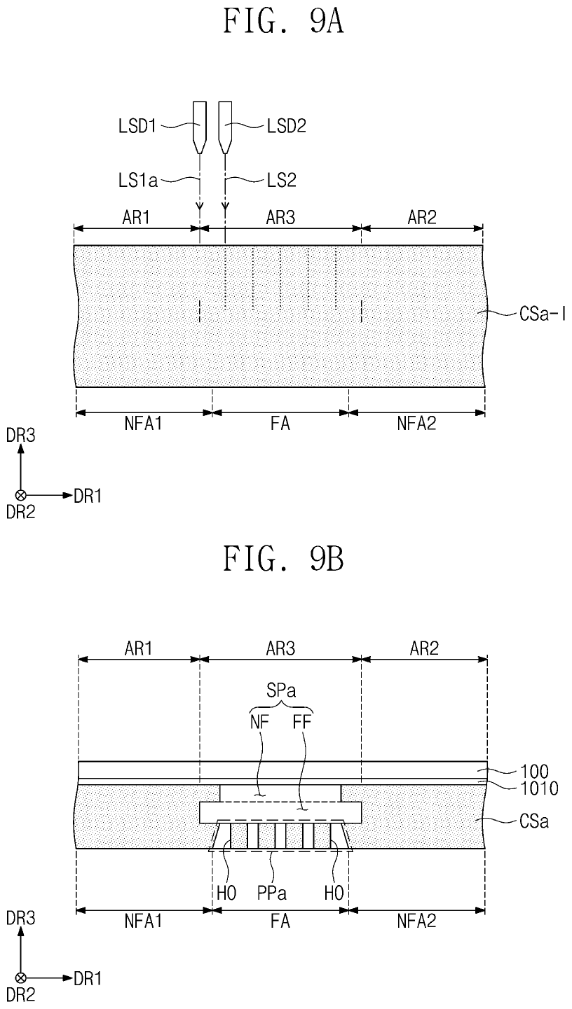

FIGS. 9A and 9B are cross-sectional views illustrating some steps of a display device manufacturing method according to embodiments of the present disclosure. FIG. 9A illustrates a cross-sectional view corresponding to FIG. 8A, and FIG. 9B illustrates a cross-sectional view corresponding to FIG. 8D. In describing FIGS. 9A and 9B, components identical or similar to the components described with reference to FIGS. 2 to 8D will be assigned with identical or similar reference numerals, and repetitive descriptions may be omitted for economy of description.

Referring to FIG. 9A, the display device manufacturing method of the present disclosure may include a step of preparing a preliminary lower substrate CSa-I, a step of applying a first laser LS1a, and a step of applying a second laser LS2.

The preliminary lower substrate CSa-I may include a first region AR1, a second region AR2, and a third region AR3. The second region AR2 may be spaced apart from the first region AR1 in the first direction DR1, and the third region AR3 may be defined between the first region AR1 and the second region AR2 (e.g., in the first direction DR1). For example, the first region AR1, the third region AR3, and the second region AR2 of the preliminary lower substrate CSa-I may be arranged in the first direction DR1. In an embodiment, the preliminary lower substrate CSa-I may have a thickness in a range of about 100 micrometers to about 500 micrometers.

A first laser device LSD1 may apply the first laser LS1a along the boundary between the first region AR1 and the third region AR3 and the boundary between the second region AR2 and the third region AR3. In an embodiment, the step of applying the first laser LS1a may include a step of focusing the first laser LS1a on a middle portion of the preliminary lower substrate CSa-I and etching a portion of the preliminary lower substrate CSa-I. The portion to which the first laser LS1a is applied may be a spacing portion SPa (refer to FIG. 9B) of a lower substrate CSa (refer to FIG. 9B) that will be described below.

Thereafter, a second laser device LSD2 may apply the second laser LS2 between the portions to which the first laser LS1a is applied. In an embodiment, the intensity of the second laser LS2 may be higher than the intensity of the first laser LS1a. The second laser LS2 may more deeply process the preliminary lower substrate CSa-I than the first laser LS1a. For example, in an embodiment the first laser LS1a may process the preliminary lower substrate CSa-I to a depth in a range of about 100 micrometers or less, and the second laser LS2 may process the preliminary lower substrate CSa-I to a depth in a range of about 100 micrometers or more.

In an embodiment, the step of applying the second laser LS2 may include a step of focusing the second laser LS2 on an upper portion of the preliminary lower substrate CSa-I and etching a portion of the preliminary lower substrate CSa-I. The portion to which the second laser LS2 is applied may be a pattern portion PPa (refer to FIG. 9B) of the lower substrate CSa (refer to FIG. 9B) that will be described below.

Although it has been described that the second laser LS2 is applied to the preliminary lower substrate CSa-I after the first laser LS1a is applied first, embodiments of the present disclosure are not necessarily limited thereto. For example, in an embodiment the first laser LS1a may be applied after the second laser LS2 is applied first, or the first laser LS1a and the second laser LS2 may be simultaneously applied. A step of forming the display panel 100 on the preliminary lower substrate CSa-I and a step of placing the etching protection film PF (refer to FIG. 8C) may be substantially the same as the processes described with reference to FIGS. 8B and 8C.

Referring to FIG. 9B, the display device manufacturing method of an embodiment of the present disclosure may include a step of forming the spacing portion SPa and the pattern portion PPa by etching the preliminary lower substrate CSa-I.

The preliminary lower substrate CSa-I may be etched from the bottom by the etchant ES (refer to FIG. 8C). In an embodiment, the etchant ES may include at least one of HF, NaOH, and KOH. However, embodiments of the present disclosure are not necessarily limited thereto. The etchant ES may infiltrate into the bottom of the preliminary lower substrate CSa-I and the portion to which the second laser LS2 is applied and may etch a portion of the preliminary lower substrate CSa-I. The pattern portion PPa of the lower substrate CSa may be formed from the etched portion.

Thereafter, an additional etching process having isotropic characteristics may be performed from the lower surface of the display panel 100 (e.g., the lower surface of the adhesive layer 1010). In the additional etching process, the etchant ES may infiltrate into the portion to which the first laser LS1a is applied and may etch a portion of the preliminary lower substrate CSa-I. The spacing portion SPa of the lower substrate CSa may be formed from the etched portion.

In an embodiment, the etched lower substrate CSa may have a thickness in a range of about 30 micrometers to about 300 micrometers. The spacing portion SPa of the lower substrate CSa may overlap the folding region FA of the display panel 100 on the plane (e.g., in the third direction DR3). In an embodiment, the spacing portion SPa may be an empty space or region. The pattern portion PPa of the lower substrate CSa may be spaced apart from the display panel 100 by the spacing portion SPa in a cross-sectional view (e.g., in the third direction DR3). The pattern portion PPa may include a plurality of holes HO. The pattern portion PPa of FIG. 9B may be substantially the same as the pattern portion PP of FIG. 8D.

The shape of the spacing portion SPa of FIG. 9B may be different from the shape of the spacing portion SP of FIG. 8D. For example, the spacing portion SPa of FIG. 9B may further include, in the spacing portion SP of FIG. 8D, a portion NF on which the first laser LS1a is not focused and that is etched by the first laser LS1a. For example, the spacing portion SPa of FIG. 9B may include a portion FF to which the first laser LS1a is applied while being focused on the middle portion and the portion NF on which the first laser LS1a is not focused and that is etched by the first laser LS1a. The width of the portion FF in the first direction DR1 may be greater than the width of the portion NF in the first direction DR1.

The display device manufacturing method of an embodiment of the present disclosure may further include a step of filling the spacing portion SPa with the resin material RM (refer to FIG. 7). In an embodiment, the resin material RM may include at least one of epoxy, urethane, and acrylate. Since the resin material RM fills the spacing portion SPa, a tensile force generated when the display device DD is folded may be decreased, and folding stability of the display device DD may be increased.

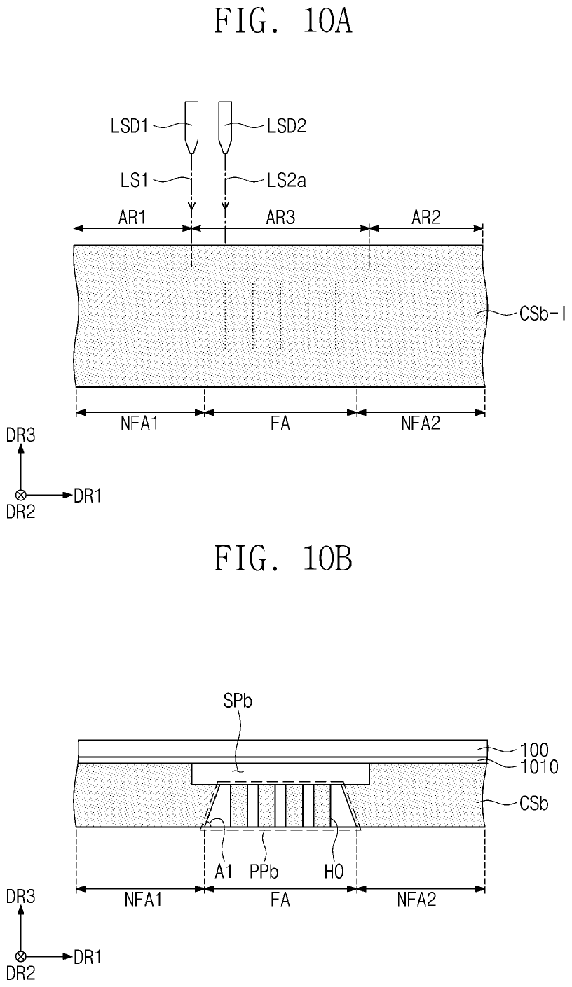

FIGS. 10A and 10B are cross-sectional views illustrating some steps of a display device manufacturing method according to embodiments of the present disclosure. FIG. 10A illustrates a cross-sectional view corresponding to FIG. 8A, and FIG. 10B illustrates a cross-sectional view corresponding to FIG. 8D. In describing FIGS. 10A and 10B, components identical or similar to the components described with reference to FIGS. 2 to 8D will be assigned with identical or similar reference numerals, and repetitive descriptions may be omitted for economy of description.

Referring to FIG. 10A, the display device manufacturing method of the present disclosure may include a step of preparing a preliminary lower substrate CSb-I, a step of applying a first laser LS1, and a step of applying a second laser LS2a.

In an embodiment, the preliminary lower substrate CSb-I may include a first region AR1, a second region AR2, and a third region AR3. The second region AR2 may be spaced apart from the first region AR1 in the first direction DR1, and the third region AR3 may be defined between the first region AR1 and the second region AR2 (e.g., in the first direction DR1). For example, the first region AR1, the third region AR3, and the second region AR2 of the preliminary lower substrate CSb-I may be arranged in the first direction DR1. In an embodiment, the preliminary lower substrate CSb-I may have a thickness in a range of about 100 micrometers to about 500 micrometers.

A first laser device LSD1 may apply the first laser LS1a along the boundary between the first region AR1 and the third region AR3 and the boundary between the second region AR2 and the third region AR3. In an embodiment, the step of applying the first laser LS1 may include a step of focusing the first laser LS1 on an upper portion of the preliminary lower substrate CSb-I and etching a portion of the preliminary lower substrate CSb-I. The portion to which the first laser LS1 is applied may be a spacing portion SPb (refer to FIG. 10B) of a lower substrate CSb (refer to FIG. 10B) that will be described below.

Thereafter, a second laser device LSD2 may apply the second laser LS2a between the portions to which the first laser LS1 is applied. In an embodiment, the intensity of the second laser LS2a may be higher than the intensity of the first laser LS1. The second laser LS2a may more deeply process the preliminary lower substrate CSb-I than the first laser LS1. For example, in an embodiment the first laser LS1 may process the preliminary lower substrate CSb-I to a depth in a range of about 100 micrometers or less, and the second laser LS2a may process the preliminary lower substrate CSb-I to a depth in a range of about 100 micrometers or more.

In an embodiment, the step of applying the second laser LS2a may include a step of focusing the second laser LS2a on a middle portion of the preliminary lower substrate CSb-I and etching a portion of the preliminary lower substrate CSb-I. The portion to which the second laser LS2a is applied may be a pattern portion PPb (refer to FIG. 10B) of the lower substrate CSb (refer to FIG. 10B) that will be described below.

Although it has been described that the second laser LS2a is applied to the preliminary lower substrate CSb-I after the first laser LS1 is applied first, embodiments of the present disclosure are not necessarily limited thereto. For example, in an embodiment the first laser LS1 may be applied after the second laser LS2a is applied first, or the first laser LS1 and the second laser LS2a may be simultaneously applied. A step of forming the display panel 100 on the preliminary lower substrate CSb-I and a step of placing the etching protection film PF (refer to FIG. 8C) may be substantially the same as the processes described with reference to FIGS. 8B and 8C.

Referring to FIG. 10B, the display device manufacturing method of an embodiment of the present disclosure may include a step of forming the spacing portion SPb and the pattern portion PPb by etching the preliminary lower substrate CSb-I.

The preliminary lower substrate CSb-I may be etched from the bottom by the etchant ES (refer to FIG. 8C). In an embodiment, the etchant ES may include at least one of HF, NaOH, and KOH. However, embodiments of the present disclosure are not necessarily limited thereto. The etchant ES may infiltrate into the bottom of the preliminary lower substrate CSb-I and the portion to which the second laser LS2a is applied and may etch a portion of the preliminary lower substrate CSb-I. The pattern portion PPb of the lower substrate CSb may be formed from the etched portion.

Thereafter, an additional etching process having isotropic characteristics may be performed from the lower surface of the display panel 100 (e.g., the lower surface of the adhesive layer 1010). In the additional etching process, the etchant ES may infiltrate into the portion to which the first laser LS1 is applied and may etch a portion of the preliminary lower substrate CSb-I. The spacing portion SPb of the lower substrate CSb may be formed from the etched portion.

In an embodiment, the etched lower substrate CSb may have a thickness in a range of about 30 micrometers to about 300 micrometers. The spacing portion SPb of the lower substrate CSb may overlap the folding region FA of the display panel 100 on the plane (e.g., in a third direction DR3). In an embodiment, the spacing portion SPb may be an empty space or region. The pattern portion PPb of the lower substrate CSb may be spaced apart from the display panel 100 by the spacing portion SPb on the section. The pattern portion PPb may include a plurality of holes HO. The angle formed by the holes HO existing at the opposite ends of the pattern portion PPb and the side surfaces of the pattern portion PPb may be defined as a first pattern angle A1. In an embodiment, the first pattern angle A1 may be in a range of about 90 degrees or less. For example, in an embodiment, the first pattern angle A1 may be in a range of about 60 degrees or less. The first pattern angle A1 of FIG. 10B may be less than the pattern angle A0 of FIG. 8D.

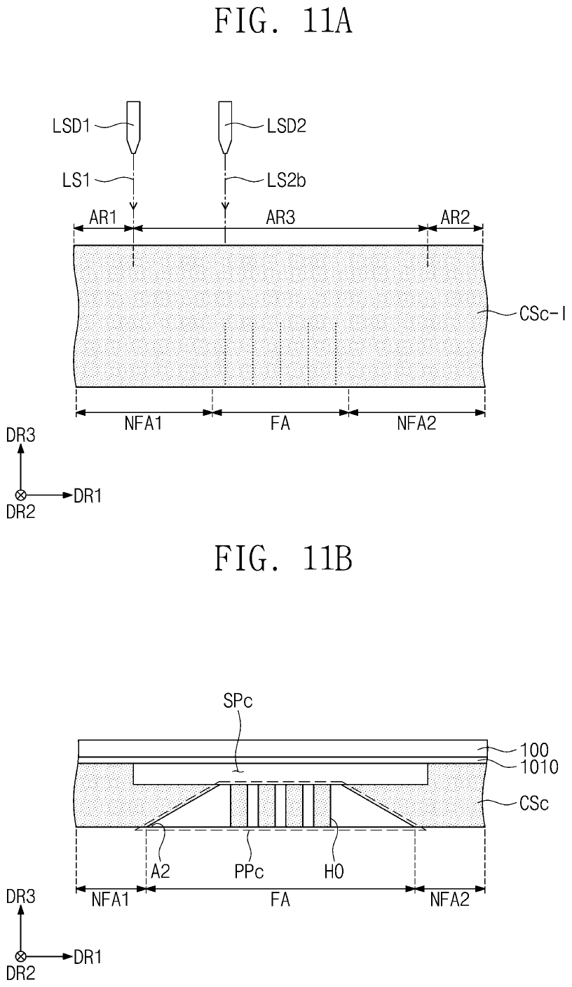

FIGS. 11A and 11B are cross-sectional views illustrating some steps of a display device manufacturing method according to embodiments of the present disclosure. FIG. 11A illustrates a cross-sectional view corresponding to FIG. 8A, and FIG. 11B illustrates a cross-sectional view corresponding to FIG. 8D. In describing FIGS. 11A and 11B, components identical or similar to the components described with reference to FIGS. 2 to 8D will be assigned with identical or similar reference numerals, and repetitive descriptions may be omitted for economy of description.

Referring to FIG. 11A, the display device manufacturing method of embodiments of the present disclosure may include a step of preparing a preliminary lower substrate CSc-I, a step of applying a first laser LS1, and a step of applying a second laser LS2b.

In an embodiment, the preliminary lower substrate CSc-I may include a first region AR1, a second region AR2, and a third region AR3. The second region AR2 may be spaced apart from the first region AR1 in the first direction DR1, and the third region AR3 may be defined between the first region AR1 and the second region AR2 (e.g., in the first direction DR1). For example, the first region AR1, the third region AR3, and the second region AR2 of the preliminary lower substrate CSc-I may be arranged in the first direction DR1. In an embodiment, the preliminary lower substrate CSc-I may have a thickness in a range of about 100 micrometers to about 500 micrometers.

A first laser device LSD1 may apply the first laser LS1a along the boundary between the first region AR1 and the third region AR3 and the boundary between the second region AR2 and the third region AR3. In an embodiment, the step of applying the first laser LS1 may include a step of focusing the first laser LS1 on an upper portion of the preliminary lower substrate CSc-I and etching a portion of the preliminary lower substrate CSc-I. The portion to which the first laser LS1 is applied may be a spacing portion SPc (refer to FIG. 11B) of a lower substrate CSc (refer to FIG. 11B) that will be described below.

Thereafter, a second laser device LSD2 may apply the second laser LS2b between the portions to which the first laser LS1 is applied. In an embodiment, the intensity of the second laser LS2b may be higher than the intensity of the first laser LS1. The second laser LS2b may more deeply process the preliminary lower substrate CSc-I than the first laser LS1. For example, in an embodiment the first laser LS1 may process the preliminary lower substrate CSc-I to a depth in a range of about 100 micrometers or less, and the second laser LS2b may process the preliminary lower substrate CSc-I to a depth in a range of about 100 micrometers or more.

In an embodiment, the step of applying the second laser LS2b may include a step of focusing the second laser LS2b on a lower portion of the preliminary lower substrate CSc-I and etching a portion of the preliminary lower substrate CSc-I. The portion to which the second laser LS2b is applied may be a pattern portion PPc (refer to FIG. 11B) of the lower substrate CSc (refer to FIG. 11B) that will be described below.

Although it has been described that the second laser LS2b is applied to the preliminary lower substrate CSc-I after the first laser LS1 is applied first, embodiments of the present disclosure are not necessarily limited thereto. For example, in an embodiment the first laser LS1 may be applied after the second laser LS2b is applied first, or the first laser LS1 and the second laser LS2b may be simultaneously applied. A step of forming the display panel 100 on the preliminary lower substrate CSc-I and a step of placing the etching protection film PF (refer to FIG. 8C) may be substantially the same as the processes described with reference to FIGS. 8B and 8C.

Referring to FIG. 11B, the display device manufacturing method of the present disclosure may include a step of forming the spacing portion SPc and the pattern portion PPc by etching the preliminary lower substrate CSc-I.

The preliminary lower substrate CSc-I may be etched from the bottom by the etchant ES (refer to FIG. 8C). In an embodiment, the etchant ES may include at least one of HF, NaOH, and KOH. However, embodiments of the present disclosure are not necessarily limited thereto. The etchant ES may infiltrate into the bottom of the preliminary lower substrate CSc-I and the portion to which the second laser LS2b is applied and may etch a portion of the preliminary lower substrate CSc-I. The pattern portion PPc of the lower substrate CSc may be formed from the etched portion.

Thereafter, an additional etching process having isotropic characteristics may be performed from the lower surface of the display panel 100 (e.g., the lower surface of the adhesive layer 1010). In the additional etching process, the etchant ES may infiltrate into the portion to which the first laser LS1 is applied and may etch a portion of the preliminary lower substrate CSc-I. The spacing portion SPc of the lower substrate CSc may be formed from the etched portion.

In an embodiment, the etched lower substrate CSc may have a thickness in a range of about 30 micrometers to about 300 micrometers. The spacing portion SPc of the lower substrate CSc may overlap the folding region FA of the display panel 100 on the plane (e.g., in the third direction DR3). In an embodiment, the spacing portion SPc may be an empty space or region. The pattern portion PPc of the lower substrate CSc may be spaced apart from the display panel 100 by the spacing portion SPc in a cross-sectional view. The pattern portion PPc may include a plurality of holes HO. The angle formed by the holes HO existing at the opposite ends of the pattern portion PPc and the side surfaces of the pattern portion PPc may be defined as a second pattern angle A2. In an embodiment, the second pattern angle A2 may be in a range of about 90 degrees or less. The second pattern angle A2 of FIG. 11B may be less than the pattern angle A0 of FIG. 8D, and the second pattern angle A2 may be less than the first pattern angle A1 of FIG. 10B.

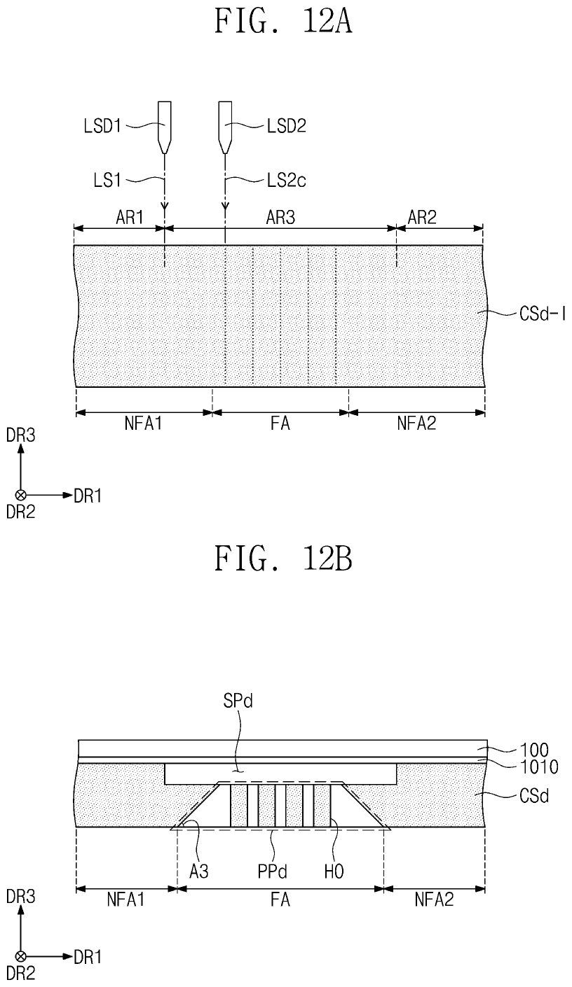

FIGS. 12A and 12B are cross-sectional views illustrating some steps of a display device manufacturing method according to embodiments of the present disclosure. FIG. 12A illustrates a cross-sectional view corresponding to FIG. 8A, and FIG. 12B illustrates a cross-sectional view corresponding to FIG. 8D. In describing FIGS. 12A and 12B, components identical or similar to the components described with reference to FIGS. 2 to 8D will be assigned with identical or similar reference numerals, and repetitive descriptions may be omitted for economy of description.

Referring to FIG. 12A, the display device manufacturing method of the present disclosure may include a step of preparing a preliminary lower substrate CSd-I, a step of applying a first laser LS1, and a step of applying a second laser LS2c.

In an embodiment, the preliminary lower substrate CSd-I may include a first region AR1, a second region AR2, and a third region AR3. The second region AR2 may be spaced apart from the first region AR1 in the first direction DR1, and the third region AR3 may be defined between the first region AR1 and the second region AR2 (e.g., in the first direction DR1). For example, the first region AR1, the third region AR3, and the second region AR2 of the preliminary lower substrate CSd-I may be arranged in the first direction DR1. In an embodiment, the preliminary lower substrate CSd-I may have a thickness in a range of about 100 micrometers to about 500 micrometers.

A first laser device LSD1 may apply the first laser LS1 along the boundary between the first region AR1 and the third region AR3 and the boundary between the second region AR2 and the third region AR3. In an embodiment, the step of applying the first laser LS1 may include a step of focusing the first laser LS1 on an upper portion of the preliminary lower substrate CSd-I and etching a portion of the preliminary lower substrate CSd-I. The portion to which the first laser LS1 is applied may be a spacing portion SPd (refer to FIG. 12B) of a lower substrate CSd (refer to FIG. 12B) that will be described below.

Thereafter, a second laser device LSD2 may apply the second laser LS2c between the portions to which the first laser LS1 is applied. In an embodiment, the intensity of the second laser LS2c may be higher than the intensity of the first laser LS1. The second laser LS2c may more deeply process the preliminary lower substrate CSd-I than the first laser LS1. For example, in an embodiment the first laser LS1 may process the preliminary lower substrate CSd-I to a depth in a range of 100 micrometers or less, and the second laser LS2c may process the preliminary lower substrate CSd-I to a depth in a range of about 100 micrometers or more.

In an embodiment, the step of applying the second laser LS2c may include a step of focusing the second laser LS2c on the upper portion, a middle portion, and a lower portion of the preliminary lower substrate CSd-I and etching a portion of the preliminary lower substrate CSd-I. The portion to which the second laser LS2c is applied may be a pattern portion PPd (refer to FIG. 12B) of the lower substrate CSd (refer to FIG. 12B) that will be described below.

Although it has been described that the second laser LS2c is applied to the preliminary lower substrate CSd-I after the first laser LS1 is applied first, embodiments of the present disclosure are not necessarily limited thereto. For example, the first laser LS1 may be applied after the second laser LS2c is applied first, or the first laser LS and the second laser LS2c may be simultaneously applied. A step of forming the display panel 100 on the preliminary lower substrate CSd-I and a step of placing the etching protection film PF (refer to FIG. 8C) may be substantially the same as the processes described with reference to FIGS. 8B and 8C.

Referring to FIG. 12B, the display device manufacturing method of an embodiment of the present disclosure may include a step of forming the spacing portion SPd and the pattern portion PPd by etching the preliminary lower substrate CSd-I.

The preliminary lower substrate CSd-I may be etched from the bottom by the etchant ES (refer to FIG. 8C). In an embodiment, the etchant ES may include at least one of HF, NaOH, and KOH. However, embodiments of the present disclosure are not necessarily limited thereto. The etchant ES may infiltrate into the bottom of the preliminary lower substrate CSd-I and the portion to which the second laser LS2c is applied and may etch a portion of the preliminary lower substrate CSd-I. The pattern portion PPd of the lower substrate CSd may be formed from the etched portion.

Thereafter, an additional etching process having isotropic characteristics may be performed from the lower surface of the display panel 100 (e.g., the lower surface of the adhesive layer 1010). In the additional etching process, the etchant ES may infiltrate into the portion to which the first laser LS1 is applied and may etch a portion of the preliminary lower substrate CSd-I. The spacing portion SPd of the lower substrate CSd may be formed from the etched portion.

In an embodiment, the etched lower substrate CSd may have a thickness in a range of about 30 micrometers to about 300 micrometers. The spacing portion SPd of the lower substrate CSd may overlap the folding region FA of the display panel 100 on the plane (e.g., in the third direction DR3). In an embodiment, the spacing portion SPd may be an empty space or region. The pattern portion PPd of the lower substrate CSd may be spaced apart from the display panel 100 by the spacing portion SPd in a cross-sectional view. The pattern portion PPd may include a plurality of holes HO. The angle formed by the holes HO existing at the opposite ends of the pattern portion PPd and the side surfaces of the pattern portion PPd may be defined as a third pattern angle A3. In an embodiment, the third pattern angle A3 may be in a range of about 90 degrees or less. The third pattern angle A3 of FIG. 12B may be less than the first pattern angle A1 of FIG. 10B and may be greater than the second pattern angle A2 of FIG. 11B. For example, in an embodiment, the third pattern angle A3 of FIG. 12B may be about 45 degrees.

As described above, the lower substrate of the display device of the present disclosure may include the spacing portion. Accordingly, tensile stress generated in the pattern portion when the display device is folded may not be transmitted to the display panel. Thus, separation between the display panel and the lower substrate may be reduced or eliminated. Furthermore, in an embodiment of the present disclosure, the spacing portion may be filled with the resin material. Accordingly, a tensile force generated when the display device is folded may be decreased, and folding stability of the display device may be increased.

In addition, in the display device manufacturing method of the present disclosure, the lower member protecting the display panel may be formed using the preliminary lower substrate without removal of the preliminary lower substrate that carries or supports the base layer of the display panel. Accordingly, the panel protection film, the cover panel, and the lower metal plate in the related art may be replaced with the preliminary lower substrate. Thus, the display device manufacturing process may be simplified, and the weight of the display device may be reduced.

While the present disclosure has been described with reference to non-limiting embodiments thereof, it will be apparent to those of ordinary skill in the art that various changes and modifications may be made thereto without departing from the spirit and scope of the present disclosure.

What is claimed is:

1. A display device comprising:
a display panel having a first non-folding region, a folding region, and a second non-folding region arranged in a first direction, wherein the folding region is adjacent to the first and second non-folding regions and is foldable about a folding axis; and
a lower substrate disposed under the display panel,
wherein the lower substrate includes a spacing portion and a pattern portion, the spacing portion overlaps the folding region on a plane, and the pattern portion is spaced apart from the display panel by the spacing portion in a thickness direction of the display device, the pattern portion including a plurality of holes.

2. The display device of claim 1, wherein a width of the pattern portion in the first direction increases as a distance from the display panel increases in the thickness direction of the display device.

3. The display device of claim 1, wherein the lower substrate includes a first region overlapping the first non-folding region, a second region overlapping the second non-folding region, and a third region overlapping the folding region, the third region including the spacing portion and the pattern portion, and wherein the first region, the second region, and the third region include a same material as each other.

4. The display device of claim 1, wherein the lower substrate is a glass substrate.

5. The display device of claim 1, wherein the spacing portion has a height that is less than or equal to one-third of a thickness of the lower substrate.

6. The display device of claim 1, wherein the spacing portion has a height in a range of about 10 micrometers to about 100 micrometers.

7. The display device of claim 1, wherein the spacing portion has a greater width in the first direction than a width of the folding region in the first direction.

8. The display device of claim 1, wherein the spacing portion has a greater width in the first direction than a width of the pattern portion in the first direction.

9. The display device of claim 1, further comprising a resin material filling the spacing portion.

10. The display device of claim 1, wherein:
the plurality of holes extends in a second direction crossing the first direction, the plurality of holes including a first hole group and a second hole group spaced apart from each other in the first direction; and
the first hole group and the second hole group are staggered with respect to each other.

11. A method for manufacturing a display device, the method comprising:
preparing a preliminary lower substrate including a first region, a second region spaced apart from the first region in a first direction, and a third region defined between the first region and the second region;
applying a first laser along a boundary of the third region;
applying a second laser between portions that the first laser is applied;
forming a display panel on the preliminary lower substrate; and
forming a spacing portion and a pattern portion by etching the preliminary lower substrate, wherein the pattern portion is spaced apart from the display panel by the spacing portion in a thickness direction of the display device, the pattern portion including a plurality of holes.

12. The method of claim 11, further comprising placing an etching protection film on the display panel.

13. The method of claim 11, further comprising filling the spacing portion with a resin material.

14. The method of claim 11, wherein the second laser has a higher intensity than an intensity of the first laser.

15. The method of claim 11, wherein the applying of the first laser includes focusing the first laser on an upper portion of the preliminary lower substrate and etching a portion of the preliminary lower substrate.

16. The method of claim 11, wherein the applying of the first laser includes focusing the first laser on a middle portion of the preliminary lower substrate and etching a portion of the preliminary lower substrate.

17. The method of claim 11, wherein the applying of the second laser includes focusing the second laser on an upper portion of the preliminary lower substrate and etching a portion of the preliminary lower substrate.

18. The method of claim 11, wherein the applying of the second laser includes focusing the second laser on a middle portion of the preliminary lower substrate and etching a portion of the preliminary lower substrate.

19. The method of claim 11, wherein the applying of the second laser includes focusing the second laser on a lower portion of the preliminary lower substrate and etching a portion of the preliminary lower substrate.

20. The method of claim 11, wherein the applying of the second laser includes focusing the second laser on an upper portion, a middle portion, and a lower portion of the preliminary lower substrate and etching a portion of the preliminary lower substrate.
